(19) United States
(12) Patent Application Publication
(10) Pub. No.: US 2014/0026950 A1
(43) Pub. Date: Jan. 30, 2014

(54) DYE SENSITIZED SOLAR CELL AND METHOD OF FORMING GEL ELECTROLYTE

(71) Applicant: Electronics and Telecommunications Research Institute, (US)

(72) Inventors: Mi Hee JUNG, Daejeon (KR); Moo Jung CHU, Daejeon (KR)

(73) Assignee: Electronics and Telecommunications Research Institute, Daejeon (KR)

(21) Appl. No.: 13/738,625

(22) Filed: Jan. 10, 2013

(30) Foreign Application Priority Data
Jul. 30, 2012 (KR) 10-2012-0083397

(51) Int. Cl. H01G 9/20; H01L 51/44

(52) U.S. Cl. CPC H01G 9/2018; H01L 51/442
USPC 136/256; 136/263; 252/62.2

(57) ABSTRACT

Provided are a gel electrolyte and a dye-sensitized solar cell with the same. The dye-sensitized solar cell may include a first electrode, a second electrode, and an electrolyte interposed between the first and second electrodes. The electrolyte may include a solvent, a hole conductor having an ester functional group, and a polymer material transforming the solvent from a liquid state to a gel state.

### CROSS-REFERENCE TO RELATED APPLICATIONS

This U.S. non-provisional patent application claims priority under 35 U.S.C. §119 to Korean Patent Application No. 10-2012-0083397, filed on Jul. 30, 2012, in the Korean Intellectual Property Office, the entire contents of which are hereby incorporated by reference.

### BACKGROUND OF THE INVENTION

Example embodiments of the inventive concept relate to a dye-sensitized solar cell, and in particular, to a dye-sensitized solar cell provided with a gel electrolyte.

A solar cell is a semiconductor device that converts the energy of light directly into electricity. Solar cell technology has been developed to realize large area, low cost, and high efficiency of the solar cell. A dye-sensitized solar cell is one type of photoelectrochemical solar cells and includes photo-sensitized dyes generating electron-hole pairs from a visible light and an oxide semiconductor layer delivering the generated electrons. The dye-sensitized solar cell may include an electrolyte. Research and development on the electrolyte are being actively conducted, because photovoltaic efficiency and durability of the solar cell are strongly dependent on the electrolyte.

### SUMMARY

Example embodiments of the inventive concept provide a gel electrolyte and a dye-sensitized solar cell provided with the same.

According to example embodiments of the inventive concepts, a dye-sensitized solar cell may include a first electrode, a second electrode, and an electrolyte interposed between the first and second electrodes. The electrolyte may include a solvent, a hole conductor having an ester functional group, and a polymer material transforming the solvent from a liquid state to a gel state.

In example embodiments, the hole conductor may be doped with anion, and the anion may be one of CF₃SO₃⁻, ClO₄⁻, BF₄⁻, and TFSI⁻.

In example embodiments, the polymer material may include first portions and second portions, the first portions being dissolved in the solvent by reacting with the solvent and the second portions participating in gelating the solvent without reaction with the solvent.

In example embodiments, the second portions of the polymer material may be cross-linked with each other, such that the solvent may be transformed from the liquid state to the gel state.

In example embodiments, the solvent may include propylene carbonate or ethylene carbonate, the hole conductor may include polypyrrole doped with anion, and the polymer material may include poly (vinylidene chloride-co-acrylonitrile) (PVDC-AN).

In example embodiments, the first electrode may include a first substrate, a metal oxide layer on the first substrate, and a first transparent conductive layer interposed between the first substrate and the metal oxide layer.

In example embodiments, the second electrode may include a second substrate, a conductive layer on the second substrate, and a second transparent conductive layer interposed between the second substrate and the conductive layer.

According to example embodiments of the inventive concepts, a method of fabricating a gel electrolyte may include providing a solvent, forming a hole conductor having an ester functional group by providing a hole conductor in the solvent, and transforming the solvent from a liquid state to a gel state by providing a polymer material in the solvent.

In example embodiments, the forming of the hole conductor having an ester functional group may include forming an amide bond between the solvent and the hole conductor.

In example embodiments, the transforming of the solvent from a liquid state to a gel state may include heating the solvent to a temperature higher than a glass transition temperature of the polymer material.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a dye-sensitized solar cell according to example embodiments of the inventive concept.

FIG. 2 is a flow chart illustrating a method of fabricating an electrolyte, according to example embodiments of the inventive concept.

FIG. 3 is a molecular structure illustrating a redox status of a hole conductor in an electrolyte, according to example embodiments of the inventive concept.

FIG. 4 is a molecular structure illustrating a chemical reaction between a solvent and a hole conductor in an electrolyte according to example embodiments of the inventive concept.

FIG. 5 is a molecular structure illustrating a process of forming a gel electrolyte using a polymer material according to example embodiments of the inventive concept.

FIG. 6 is a graph showing current-voltage characteristics of dye-sensitized solar cells including electrolytes formed by an experimental example and a comparative example, respectively.

FIG. 7 is a graph showing external quantum efficiencies of dye-sensitized solar cells including electrolytes formed by an experimental example and a comparative example, respectively.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

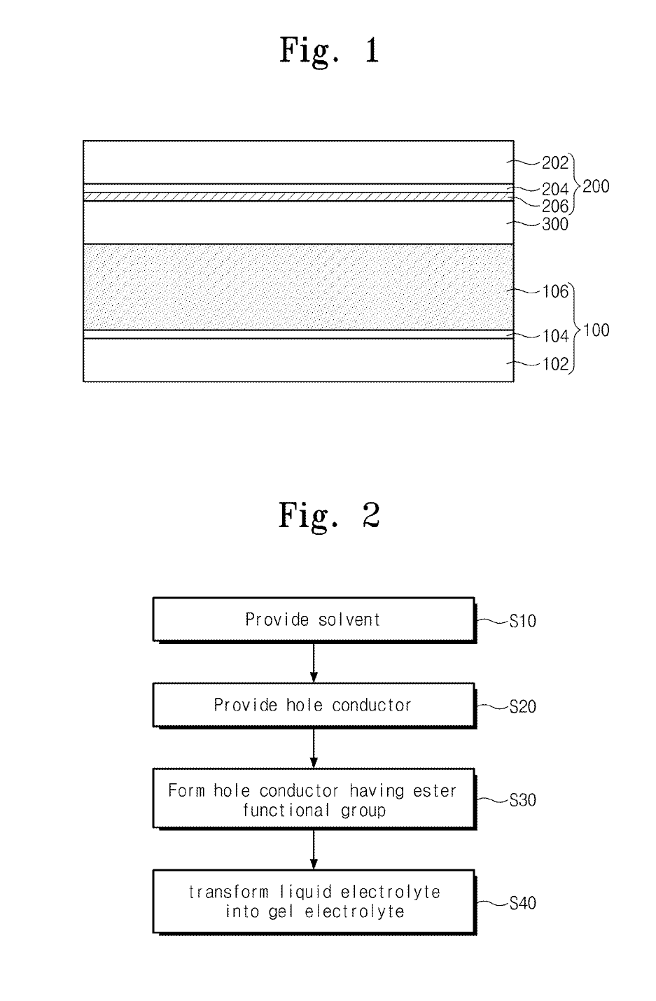

FIG. 1 is a sectional view illustrating a dye-sensitized solar cell according to example embodiments of the inventive concept.

Referring to FIG. 1, a dye-sensitized solar cell may include a first electrode 100, a second electrode 200, and an electrolyte 300 interposed between the first electrode 100 and the second electrode 200.

The first electrode 100 may serve as a cathode of the solar cell. The first electrode 100 may include a first substrate 102, a metal oxide layer 106 provided on the first substrate 102, and a first transparent conductive layer 104 interposed between the first substrate 102 and the metal oxide layer 106.

The first substrate 102 may be, for example, a transparent organic substrate, or a transparent and flexible polymer substrate. The first transparent conductive layer 104 may be, for example, an indium-tin oxide (ITO) layer, an F-doped SnO₂ (FTO) layer, or an ITO layer coated with an antimony-tin oxide (ATO) layer or an FTO layer. The metal oxide layer 106 may be a metal oxide layer adsorbed with dye molecules. The metal oxide layer 106 may include, for example, titanium oxide, tin oxide and/or zinc oxide. The dye molecules may include, for example, ruthenium complexes, which can absorb a visible light. In example embodiments, the dye molecules may include a xanthine-based dye (such as rhodamine B, rose Bengal, eosin, and erythrocin), a cyanin-based dye (such as quinocyanin and cryptocyanin), a basic dye (such as phenosafranine, capri-blue, tyrosine, and methylene blue), a porphyrin-based compound (such as chlorophyll, Zn porphyrin, and Mg porphyrin), an azo-based dye, a phthalocyanine compound, an anthraquinone-based dye, polycyclic quinone-based dye, or any mixture thereof.

The second electrode 200 may serve as an anode of the solar cell. The second electrode 200 may include a second substrate 202, a conductive layer 206 provided on the second substrate 202, and a second transparent conductive layer 204 interposed between the second substrate 202 and the conductive layer 206. The conductive layer 206 and the second transparent conductive layer 204 may be provided in such a way that they are interposed between the second substrate 202 and the first substrate 102.

The second substrate 202 may be, for example, a transparent organic substrate or a transparent and flexible polymer substrate. The second transparent conductive layer 204 may be, for example, an indium-tin oxide (ITO) layer, an F-doped SnO₂ (FTO) layer, or an ITO layer coated with an antimony-tin oxide (ATO) layer or an FTO layer. The conductive layer 206 may include, for example, platinum, carbon particles, conductive polymer, or any mixture thereof.

The electrolyte 300 may be provided to fill a gap between the first electrode 100 and the second electrode 200. The electrolyte 300 may include at least one of solvents, redox pairs, hole conductors, or polymer materials.

The solvents may include, for example, propylene carbonate and/or ethylene carbonate. The redox pairs may be, for example, I⁻ and I₃⁻. Phyridium iodine may be used as a source of iodine that is provided in the electrolyte 300 to participate in an oxidation-reduction reaction. For example, the phyridium iodine may be 1-butylpyridinium iodide. I⁻ may provide electrons to the first electrode 100 serving as the cathode and be oxidized to form I₃⁻. I₃⁻ may be supplied with electrons from the second electrode 200 serving as the anode and be reduced to form I⁻.

The hole conductor may include, for example, doped-polypyrrole. The hole conductor may be doped with anions, which may be one of CF₃SO₃⁻, ClO₄⁻, BF₄⁻, and TFSI⁻(trifluoromethanesulfonimide,[(CF₃SO₂)₂N]⁻). The hole conductor may be reacted with the solvent to produce a hole conductor having ester functional group.

The polymer material may be a block copolymer. A glass transition temperature (Tg) of the polymer material may be less than about 100° C. The polymer material may include first portions and second portions. The first portions of the polymer material may be reacted with the solvent and dissolved in the solvent. The second portions of the polymer material may not be reacted with the solvent and be cross-linked with each other. As the result of the cross-linking reaction between the second portions, the solvent may be gelated. For example, the polymer material may be poly(vinylidene chloride-co-acrylonitrile) (PVDC-AN).

An operational principle of the dye-sensitized solar cell will be described in brief.

When visible light is absorbed by the metal oxide layer 106 adsorbed with dye molecules, electron-hole pairs may be produced in the dye molecules. The electrons may be injected into a conduction band of the metal oxide layer 106 and delivered into the first transparent conductive layer 104 to generate an electric current. The holes generated in the dye molecules may be supplied with electrons from the electrolyte 300 to be reduced. The dye-sensitized solar cell may operate based on this process of electron circulation.

FIG. 2 is a flow chart illustrating a method of fabricating an electrolyte, according to example embodiments of the inventive concept.

Referring to FIG. 2, a solvent may be provided (in S10). Phyridium iodine may be provided in the solvent to serve as a source of redox pairs. In example embodiments, the solvent may be about 2 ml propylene carbonate, and about 0.6M 1-butylpyridinium iodide may be provided in the solvent as the source of redox pairs.

A hole conductor may be provided in the solvent (in S20). In example embodiments, the hole conductor may be about 200 μl doped polypyrrole. The polypyrrole may be doped with anions, which may be one of CF₃SO₃⁻, ClO₄⁻, BF₄⁻, and TFSI⁻.

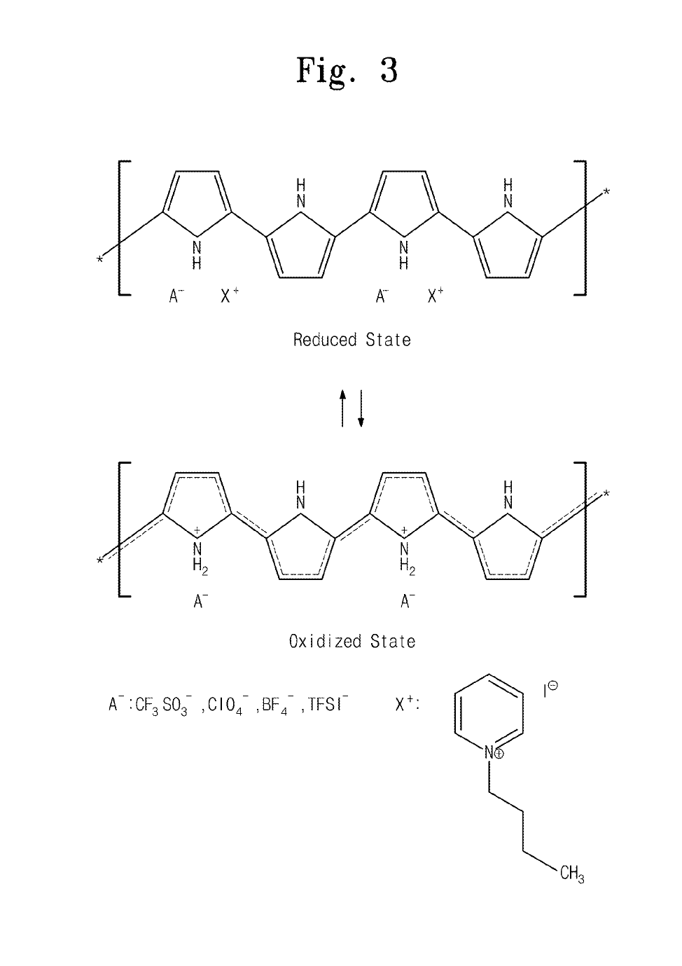

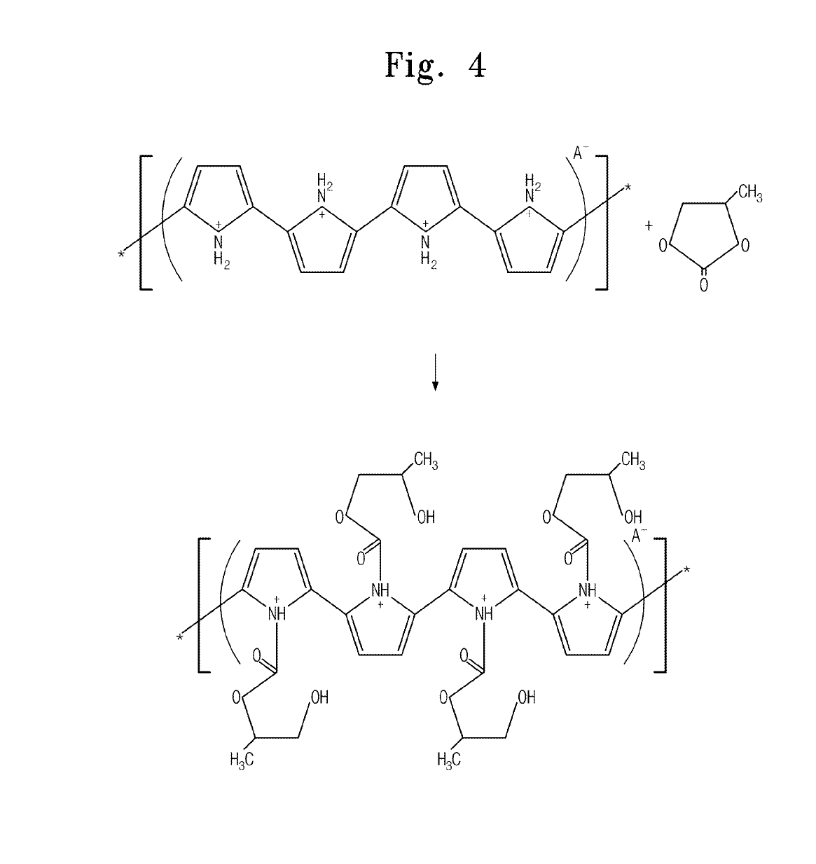

FIG. 3 is a molecular structure illustrating a redox status of a hole conductor in an electrolyte, according to example embodiments of the inventive concept.

Referring to FIG. 3, the hole conductor may be polypyrrole doped with anions (A⁻), where the anion (A⁻) may be one of CF₃SO₃⁻, ClO₄⁻, BF₄⁻, and TFSI⁻ ([(CF₃SO₂₂N]⁻). The polypyrrole doped with anions (A⁻) may be in an oxidized state with nitrogen cation (N⁺). During the reduction process in the electrolyte 300, the polypyrrole doped with anions (A⁻) may be bound with cation (X⁺) in the electrolyte 300 to be in a reduced state. The cation (X⁺) may be 1-butylpyridinium iodide.

Referring back to FIG. 2, the solvent and the hole conductor may be reacted with each other to form a hole conductor having ester functional group (in S30).

FIG. 4 is a molecular structure illustrating a chemical reaction between a solvent and a hole conductor in an electrolyte according to example embodiments of the inventive concept.

Referring to FIG. 4, propylene carbonate used as the solvent may be bonded with polypyrrole doped with anions (A-) used as the hole conductor, to form an amide bond and produce a hole conductor having an ester functional group. The solvent and the hole conductor may be reacted with each other at a temperature of about 10-40° C. The hole conductor having an ester functional group may have a three-dimensional structure. A hole conductor having a three-dimensional structure may have hole conductivity higher than that of a hole conductor having a line structure. As the result of the use of the hole conductor having an ester functional group, it is possible to realize a dye-sensitized solar cell having high hole conductivity.

Referring back to FIG. 2, a polymer material may be provided in the solvent to transform a liquid electrolyte into a gel electrolyte (in S40). The polymer material may be a block copolymer, whose glass transition temperature is less than about 100° C. For example, the polymer material provided in the solvent may be poly (vinylidene chloride-co-acrylonitrile) (PVDC-AN) (of about 7 wt %), whose glass transition temperature is about 52° C. Thereafter, the solvent may be heated to a temperature higher than the glass transition temperature of the polymer material, and thus, the liquid electrolyte may be transformed into the gel electrolyte.

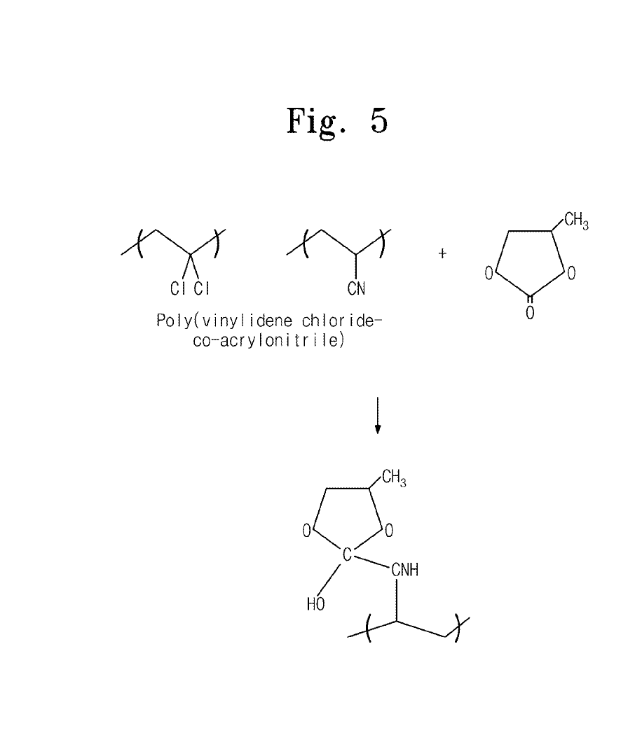

FIG. 5 is a molecular structure illustrating a process of forming a gel electrolyte using a polymer material according to example embodiments of the inventive concept.

Referring to FIG. 5, the polymer material may be poly (vinylidene chloride-co-acrylonitrile) (PVDC-AN). Acrylonitrile of PVDC-AN may be reacted with the solvent and dissolved in the solvent. Vinylidene chloride of PVDC-AN may be cross-linked with each other to form a gel solvent. Since PVDC-AN contains Cl with high electronegativity, the electrolyte 300 may have high electron mobility.

In general, the dye-sensitized solar cell may include a liquid electrolyte using a volatile organic solvent. The liquid electrolyte may exhibit high photoelectric conversion efficiency, owing to its high ion conductivity. However, a solar cell using the liquid electrolyte may exhibit poor durability, because the liquid electrolyte is apt to be leaked or evaporated. Accordingly, in the case where the electrolyte 300 is transformed from the liquid state to the gel state, it is possible to prevent the above problems of the dye-sensitized solar cell (for example, leakage, evaporation, corrosion of the electrolyte).

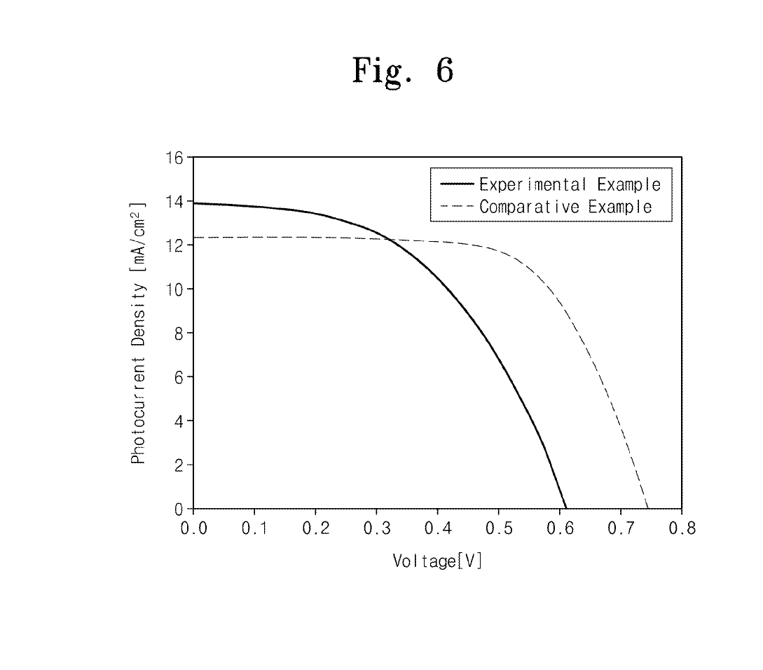

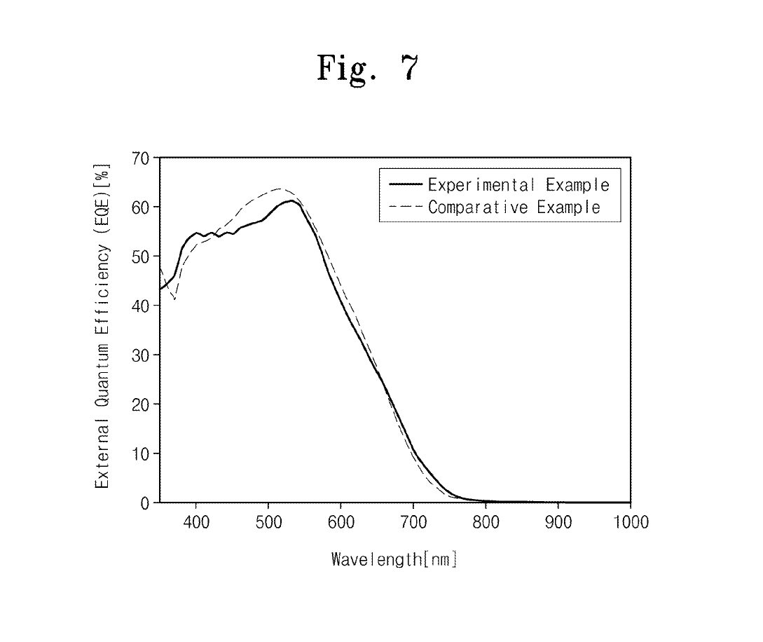

FIG. 6 is a graph showing current-voltage characteristics of dye-sensitized solar cells including electrolytes formed by an experimental example and a comparative example, respectively, and FIG. 7 is a graph showing external quantum efficiencies of dye-sensitized solar cells including electrolytes formed by an experimental example and a comparative example, respectively.

### FORMATION: EXPERIMENTAL EXAMPLE

A gel electrolyte was formed using the method according to example embodiments of the inventive concept. The solvent was 2 ml propylene carbonate, and a source of redox pairs was 1-butylpyridinium iodide whose concentration was about 0.6M with respect to the solvent. The hole conductor was polypyrrole doped with anions. The doped polypyrrole was 200 μl. 7 wt % of PVDC-AN, whose glass transition temperature is 52° C., was added into the electrolyte. Thereafter, the resulting material was heated to a temperature higher than the glass transition temperature (i.e., 52° C.) of PVDC-AN, thereby forming a gel electrolyte.

### FORMATION: COMPARATIVE EXAMPLE

A liquid electrolyte was formed using a conventional method. The solvent was a mixed solution of acetonitrile and valeronitrile. In the mixed solution, a volume ratio of acetonitrile to valeronitrile was 85:15. To form a liquid electrolyte, 0.6M of 1-hexy-2,3-dimethylimidazolium iodide, 0.03M of iodine, 0.1M of guanidine thiocyanate, and 0.5M of 4-tert-butyl pyridine were added in the solvent.

Referring to FIG. 6, when a voltage is less than about 0.3 volt, a photocurrent density was higher in the experimental example than in the comparative example.

Photovoltaic properties of dye-sensitized solar cells according to the experimental and comparative examples were as follows:

TABLE 1

| | Isc [mA/cm2] | Voc [V] | FF [%] | η [%] |
|---|---|---|---|---|
| comparative example | 12.33 | 0.75 | 65.30 | 5.99 |
| embodiment | 13.88 | 0.61 | 49.40 | 4.19 |

where Isc denotes a photocurrent density in a short circuit and Voc does a voltage in an open circuit. FF(fill factor) denotes a ratio of a product of Voc and Isc to a maximum power, and η does photoelectric conversion efficiency. As shown in the Table 1, under the 1 sun (ΛM 1.5, 100 mW/cm²), photoelectric conversion efficiency η was 4.19% in the gel electrolyte according to the experimental example and was 5.99% in the liquid electrolyte according to the comparative example. In other words, photoelectric conversion efficiency of the gel electrolyte according to the experimental example was about 70% of that of the liquid electrolyte according to the comparative example.

Referring to FIG. 7, the maximum optical absorptivity of dye was at a wavelength of about 530 nm. At the wavelength of about 530 nm, external quantum efficiency was about 63% in the liquid electrolyte according to the comparative example and was about 60% in the gel electrolyte according to the experimental example. This shows that the conventional liquid electrolyte can be replaced with the gel electrolyte according to example embodiments of the inventive concept.

According to example embodiments of the inventive concept, due to the use of the gel electrolyte, it is possible to prevent the electrolyte from being leaked and evaporated. The enables to improve durability of the electrolyte.

In addition, the solvent and the hole conductor are bonded with each other, and this enables to increase hole mobility of the electrolyte and to improve efficiency of the dye-sensitized solar cell.

While example embodiments of the inventive concepts have been particularly shown and described, it will be understood by one of ordinary skill in the art that variations in form and detail may be made therein without departing from the spirit and scope of the attached claims.

What is claimed is:

1. A dye-sensitized solar cell, comprising:
a first electrode;
a second electrode; and
an electrolyte interposed between the first and second electrodes,
wherein the electrolyte comprises:
a solvent;
a hole conductor having an ester functional group; and
a polymer material transforming the solvent from a liquid state to a gel state.

2. The dye-sensitized solar cell of claim 1, wherein the hole conductor having an ester functional group is doped with anion.

3. The dye-sensitized solar cell of claim 2, wherein the anion is one of CF₃SO₃⁻, ClO₄⁻, BF₄⁻, and TESI⁻.

4. The dye-sensitized solar cell of claim 1, wherein the polymer material comprises first portions and second portions, the first portions being dissolved in the solvent by reacting with the solvent and the second portions participating in gelating the solvent without reaction with the solvent.

5. The dye-sensitized solar cell of claim 4, wherein the second portions of the polymer material are cross-linked with each other, such that the solvent is transformed from the liquid state to the gel state.

6. The dye-sensitized solar cell of claim 1, wherein the solvent comprises propylene carbonate or ethylene carbonate.

7. The dye-sensitized solar cell of claim 1, wherein the hole conductor having an ester functional group comprises polypyrrole doped with anion.

8. The dye-sensitized solar cell of claim 1, wherein the polymer material comprises poly (vinylidene chloride-co-acrylonitrile) (PVDC-AN).

9. The dye-sensitized solar cell of claim 1, wherein the first electrode comprises:
a first substrate;
a metal oxide layer on the first substrate; and
a first transparent conductive layer interposed between the first substrate and the metal oxide layer.

10. The dye-sensitized solar cell of claim 1, wherein the second electrode comprises:
a second substrate;
a conductive layer on the second substrate; and
a second transparent conductive layer interposed between the second substrate and the conductive layer.

11. A method of fabricating a gel electrolyte, comprising:
providing a solvent;
forming a hole conductor having an ester functional group by providing a hole conductor in the solvent; and
transforming the solvent from a liquid state to a gel state by providing a polymer material in the solvent.

12. The method of claim 11, wherein the hole conductor is doped with anion, and the anion is one of CF₃SO₃⁻, ClO₄⁻, BF₄⁻, and TFSI⁻.

13. The method of claim 12, wherein the hole conductor comprises polypyrrole doped with anion.

14. The method of claim 11, wherein the forming of the hole conductor having an ester functional group comprises forming an amide bond between the solvent and the hole conductor.

15. The method of claim 11, wherein the polymer material comprises first portions and second portions, the first portions being dissolved in the solvent by reacting with the solvent and the second portions participating in gelating the solvent without reaction with the solvent.

16. The method of claim 15, wherein the polymer material comprises poly (vinylidene chloride-co-acrylonitrile) (PVDC-AN).

17. The method of claim 11, wherein the transforming of the solvent from a liquid state to a gel state comprises heating the solvent to a temperature higher than a glass transition temperature of the polymer material.
